(19) United States
(12) Patent Application Publication
(10) Pub. No.: US 2026/0371750 A1
(43) Pub. Date: Nov. 19, 2026

(54) SILICON INTERDIGITATED STRUCTURE FOR DIRECT-DEPOSIT INFRARED FOCAL PLANE ARRAYS

(71) Applicant: TRUSTEES OF DARTMOUTH COLLEGE, Hanover, NH (US)

(72) Inventors: Jifeng LIU, Hanover, NH (US); Xiaoxin WANG, Hanover, NH (US); Kaitlin M. ANAGNOST, Torrance, CA (US); Eric R. FOSSUM, Wolfeboro, NH (US)

(73) Assignee: TRUSTEES OF DARTMOUTH COLLEGE, Hanover, NH (US)

(21) Appl. No.: 18/732,196

(22) Filed: Jun. 3, 2024

Related U.S. Application Data
(60) Provisional application No. 63/505,955, filed on Jun. 2, 2023.

(51) Int. Cl. H10F 39/18; H10F 39/00

(52) U.S. Cl. CPC H10F 39/184; H10F 39/014; H10F 39/021

(57) ABSTRACT

An infrared (IR) detector includes a complementary metal oxide semiconductor (CMOS) image sensor; and an IR absorber layer formed on the CMOS image sensor. The CMOS image sensor includes an interdigital silicon layer. the IR absorber layer includes Ge₁₋ₓSnₓ, Ge_{0.89}Sn_{0.11}, or In_{0.1}Ga_{0.9}Sb.

### CROSS REFERENCE TO RELATED APPLICATIONS

This present disclosure claims the benefit of U.S. Provisional Application No. 63/505,955, filed on Jun. 2, 2023, which is incorporated herein by reference in its entirety for all purposes.

### STATEMENT REGARDING FEDERALLY SPONSORED RESEARCH OR DEVELOPMENT

This invention was made with government support under grant number FA9550-19-1-0341 awarded by the Air Force Office of Scientific Research. The government has certain rights in the invention.

### FIELD

The present disclosure relates to Si-based infrared (IR) sensors.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

IR imaging has many uses, including in light detection and ranging, security, medical, and more. There is a desire to transition towards Si-based infrared (IR) sensors due to easier readout, potentially lower readout noise, and other circuit integration on-chip. Further, such IR sensors are expected to avoid the manufacturing, scalability, and thermal reliability challenges HgCdTe and other hybrid sensors face. However, without an IR absorption layer, Si has a weak IR response because of its 1.12 eV bandgap.

### SUMMARY

The present disclosure relates to an infrared (IR) detector, including a complementary metal oxide semiconductor (CMOS) image sensor; and an IR absorber layer formed on the CMOS image sensor

In one embodiment, the CMOS image sensor includes an interdigital silicon layer.

In one embodiment, the IR absorber layer directly contacts the silicon layer.

In one embodiment, the IR absorber layer includes Ge₁₋ₓSnₓ.

In one embodiment, the IR absorber layer includes Ge_{0.89}Sn_{0.11}.

In one embodiment, the IR absorber layer includes In_{0.1}Ga_{0.9}Sb.

In one embodiment, the CMOS image sensor is a silicon-based CMOS image sensor.

In one embodiment, the IR absorber layer is a p-type IR absorber layer.

In one embodiment, the CMOS image sensor includes an n-type silicon storage well and a partial p⁺ silicon pinning region; and the p-type IR absorber layer, when struck by photons, generates and diffuses photoelectrons and holes into the n-type silicon storage well and the partial p⁺ silicon pinning region, respectively.

The disclosure additionally relates to a method for fabricating an IR detector, including forming an interdigitated silicon layer on a substrate including alternating n-type silicon and p+ silicon fingers; and forming an IR absorber layer adjacent to and contacting the interdigitated silicon layer, the IR absorber layer being p-type.

Note that this summary does not specify every embodiment and/or incrementally novel aspect of the present disclosure or claimed inventions. Instead, this summary only provides a preliminary discussion of different embodiments and corresponding points of novelty. For additional details and/or possible perspectives of the disclosure and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1 is a schematic of an IR-absorbing layer on interdigitated silicon layer, according to one embodiment of the present disclosure.

FIG. 2A is a graph showing the calculated band structure for Ge_{0.89}Sn_{0.11} along Cutline 1 in FIG. 1, according to one embodiment of the present disclosure.

FIG. 2B is a graph showing the calculated band structure for Ge_{0.89}Sn_{0.11} along Cutline 2 in FIG. 1, according to one embodiment of the present disclosure.

FIG. 3A is a graph showing the calculated band structure for In_{0.1}Ga_{0.9}Sb along Cutline 1 in FIG. 1, according to one embodiment of the present disclosure.

FIG. 3B is a graph showing the calculated band structure for In_{0.1}Ga_{0.9}Sb along Cutline 2 in FIG. 1, according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Described herein is a new structural integration method and device for p-type infrared (IR) absorbers directly on silicon (Si)-based CMOS image sensors (CIS) with type-II band alignment. The method and device are explored by calculation as an alternative to hybrid IR detectors. In the sensor described herein, photons strike a p-type IR absorption layer that forms a type-II heterostructure on Si, generating photoelectrons that diffuse into the pixel's n-type Si storage well, leaving the holes in the p⁺ Si pinning region. Depositing the IR absorber directly on silicon can negate the use of metal hybrid bonds or bump bonds typically used in many IR detectors. Aside from reliability concerns during thermal cycling and yield, a metal interconnect implies a 3-T type readout with residual kTC noise and potential lag. Direct injection of photoelectrons into Si can permit low-noise 4-T readout.

Ge_{0.89}Sn_{0.11} and In_{0.1}Ga_{0.9}Sb can be considered as possible materials for the IR absorption layer. Like HgCdTe, GeSn can have a direct, tunable bandgap, but is CMOS- and Si-compatible, and thus more scalable. Experimental results verify proof-of-concept with 100 mA/W responsivity at ~2 μm compatible with back-end-of-line CMOS processing. III-V materials like InGaSb can also have direct bandgaps and can be easier to manufacture than II-VI compounds.

To advance this approach towards use on a CIS, the electron diffusion and subsequent readout can first be optimized via an interdigitated structure. Deposition layer thickness, minimum interdigitated structure width, target wavelength, quantum efficiency, and dark current can then be calculated to further characterize the proposed device.

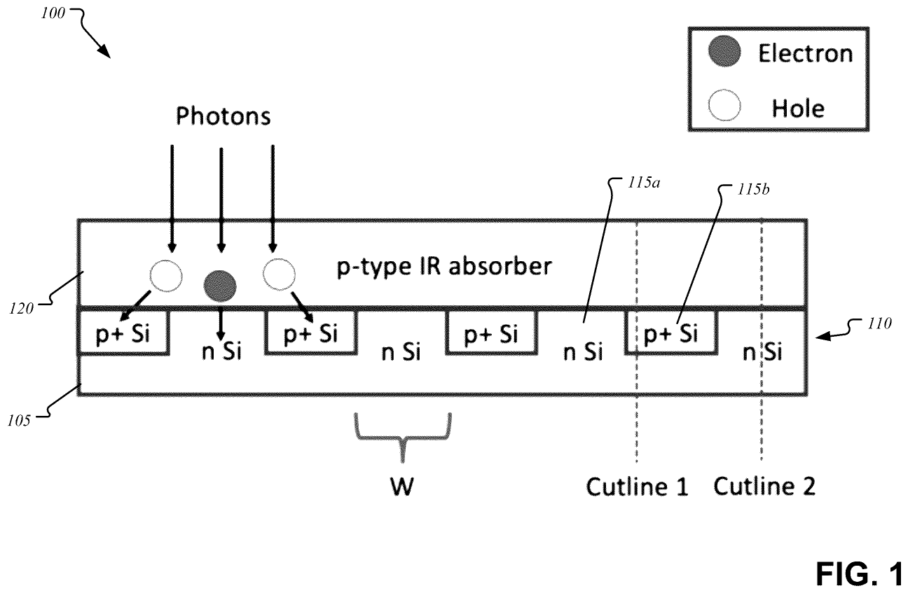

To this end, FIG. 1 is a schematic of an IR-absorbing layer on an interdigitated silicon layer, according to one embodiment of the present disclosure. In one embodiment, some photoelectrons can diffuse to locations that will not be readout if the IR absorber is deposited over the entire p+ Si pinning layer used in frontside-illuminated devices. Therefore, an interdigitated Si layer with p+ and n type regions, equivalently a partial pinning layer, can be considered as shown in FIG. 1.

In one embodiment, as shown, an interdigitated IR detector 100 includes a substrate layer 105. The substrate layer 105 can include an interdigitated surface 110. A material of the substrate layer 105 can be, for example, n-type Si. The interdigitated surface 110 can be designed to include one or more “fingers” 115a or raised structures relative to a plane of the substrate layer 105. The interdigitated surface 110 can include gaps or spaces for a complementary set of fingers 115b formed within the gaps and contacting the one or more fingers 115a of the interdigitated surface 110. A material of the complementary set of fingers 115b can be, for example, p-type silicon. The one or more fingers 115a can be, for example, an n-type silicon storage well. The complementary set of fingers 115b can be, for example, the partial p⁺ Si pinning region. Together, the substrate layer 105, the interdigitated surface 110 with the one or more fingers 115a, and the complementary set of fingers 115b can form a CMOS image sensor.

The interdigitated IR detector 100 can include an absorber layer 120 adjacent to the interdigitated surface 110 having the complementary set of fingers 115b formed therein. The absorber layer 120 can be configured to absorb, for example, IR radiation. A material of the absorber layer 120 can be, for example, a p-type IR radiation absorbing material. The absorber layer 120 can be configured to absorb photos and generate and diffuse photoelectrons and holes. Thus, the one or more fingers 115a (the n-type silicon storage well) and the complementary set of fingers 115b (the partial p⁺ silicon pinning region) of the CMOS image sensor can be configured to absorb the generated photoelectrons and holes, respectively.

In one embodiment, the interdigitated IR detector 100 is fabricated via with an interdigitated mask for p+ pinning layer implantation. An example fabrication process is described herein. A first pattern can be applied to the substrate layer 105 using, for example, a first photoresist layer applied to the substrate layer with a first mask applied to the first photoresist layer and a first exposure process applied to the first mask. A first development process can be used to develop the first photoresist layer and remove predetermined portions of the first photoresist layer affected by the first exposure process. A first removal process can be applied to the substrate layer 105 having the developed first photoresist layer thereon, wherein the first removal process can remove exposed portions of the substrate layer 105 (e.g., portions of the substrate layer 105 not protected by the developed first photoresist layer). For example, the first removal process can be a chemical (wet) etch or a physical (dry) etch. The first removal process can form the interdigitated surface 110 with the one or more fingers 115a based on the first pattern, which can be reflected in pattern of the first mask (based on whether the photoresist of the first photoresist layer is a negative photoresist or a positive photoresist).

In one embodiment, the complementary set of fingers 115b can be formed in the gaps of the interdigitated surface 110 and contact the one or more interdigitated fingers 115a. For example, the complementary set of fingers 115b can be deposited or grown.

In one embodiment, the absorber layer 120 is formed adjacent to the interdigitated surface 110 having the complementary set of fingers 115b formed therein. For example, the absorber layer 120 can be deposited or grown.

In one embodiment, the absorber layer 120 includes Ge₁₋ₓSnₓ.

In one embodiment, the absorber layer 120 includes Ge_{0.89}Sn_{0.11}.

In one embodiment, the absorber layer 120 includes In_{0.1}Ga_{0.9}Sb.

In one embodiment, the CMOS image sensor is a silicon-based CMOS image sensor.

In one embodiment, the IR-absorber/Si band structures are calculated using the Anderson approach, which utilizes the vacuum level to find the valence band offset. The difference in conduction band energies ΔE_{c} can be the difference between the Si and IR absorbers' affinities, qχ_{Si} and qχ_{absorber}, respectively. Using the direct bandgap of the IR absorber and indirect bandgap of Si (1.12 eV), the difference in IR absorber and Si bandgaps ΔEg can be determined, and thus valence band energies ΔEᵥ:

ΔEᵥ=ΔE_{g}−ΔE_{c} (1)

Assuming Si's vacuum level is qχ_{Si}=4.05 eV, since E_{c}=Eᵥ+E_{g}, Si's E_{c} and Eᵥ can be determined, and ΔEᵥ, ΔE_{c}, and ΔE_{g} can be used to find those of the absorbers.

To calculate the Fermi level E_{F}, the density of states in the conduction band N_{c} and valence band Nᵥ can first be determined using:

$${N}_{C} = {2 [ \frac{{m}_{n}^{*} kT}{2 π {ℏ}^{2}} ]}^{3 / 2} , and$$

$${N}_{V} = {2 [ \frac{{m}_{p}^{*} kT}{2 π {ℏ}^{2}} ]}^{3 / 2} .$$

The intrinsic Fermi level Eᵢ and intrinsic carrier concentration nᵢ can then be determined via

$${E}_{i} = \frac{{E}_{C} + {E}_{V}}{2} + \frac{3}{4} kT ln ( \frac{{m}_{p}^{*}}{{m}_{n}^{*}} ) , and$$

$${n}_{i} . = \sqrt{{N}_{C} {N}_{V}} {e}^{- {E}_{g} / 2 kT} .$$

Finally, E_{F} can be determined via

$${E}_{F} = kT ln \frac{{N}_{D}}{{n}_{i}} , and$$

$${E}_{i} = kT ln \frac{{N}_{A}}{{n}_{i}} .$$

The depletion region widths on each side of the junction can be determined using

$${W}_{D 1} = {[ \frac{2 {N}_{A 2} {ε}_{S 1} {ε}_{S 2} ( {Ψ}_{bi} - V )}{q {N}_{D 1} ( {ε}_{S 1} {N}_{D 1} + {ε}_{S 2} {N}_{A 2} )} ]}^{1 / 2} , and$$

$${W}_{D 2} = {[ \frac{2 {N}_{D 1} {ε}_{s 1} ε s 2 ( {Ψ}_{b i} - V )}{q {N}_{A 2} ( {ε}_{S 1} {N}_{D 1} + {ε}_{s 2} {N}_{A 2} )} ]}^{1 / 2} .$$

The Debye lengths L_{D} can be determined and compared to the depletion widths to validate the analyses.

The band bending present in the IR absorbers and Si can be found. The sum of the interface potentials for the absorber and Si, qψ_{absorber}+qψ_{Si}=qψ_{bi} and with 0 V applied, can be related by

$${Ψ}_{p} = \frac{{qN}_{A} {W}_{Dp}^{2}}{2 {ε}_{s}} , and$$

$$\vert {Ψ}_{n} \vert = \frac{{qN}_{D} {W}_{Dn}^{2}}{2 {ε}_{s}} .$$

The Fermi levels of the materials can then be aligned at 0 eV for simplicity.

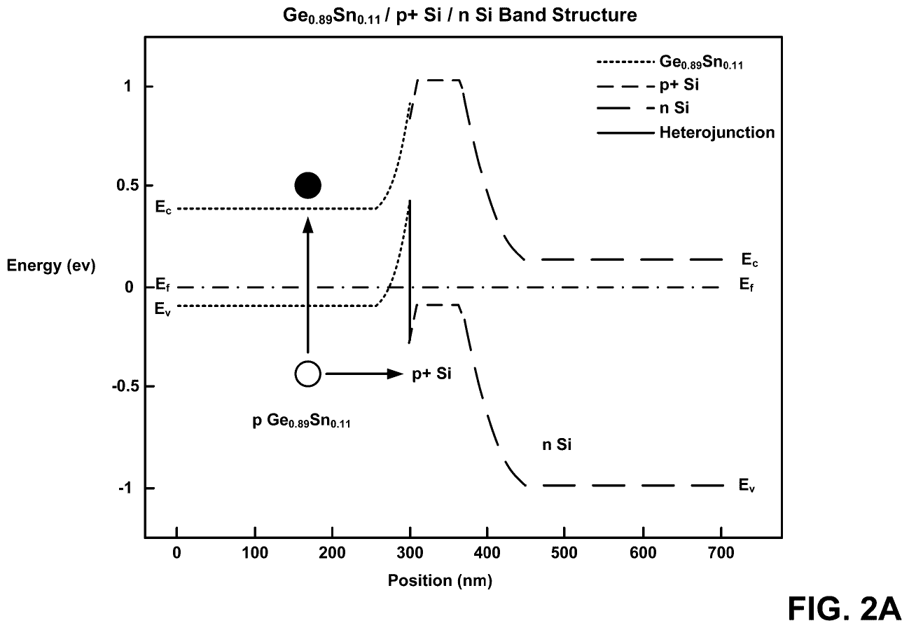

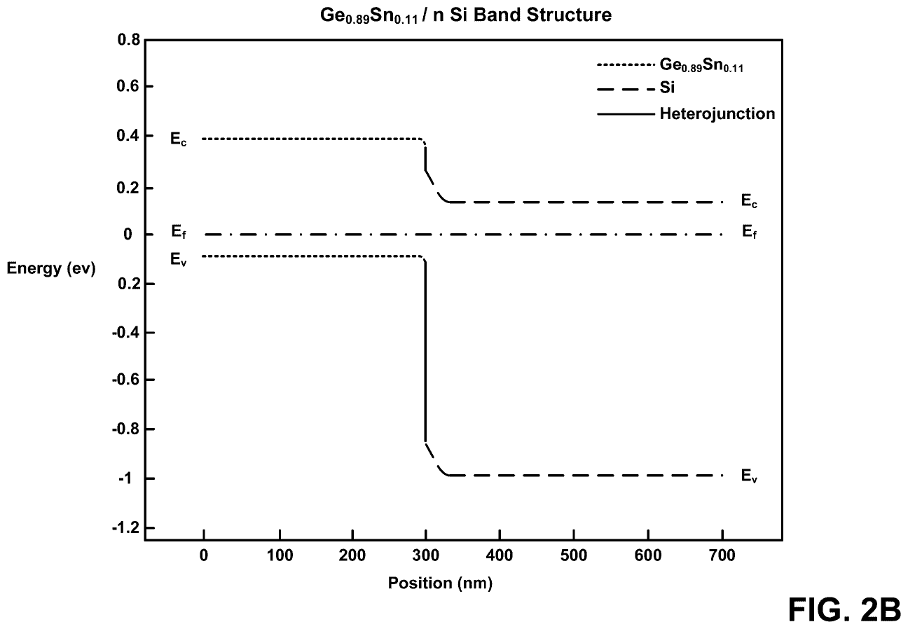

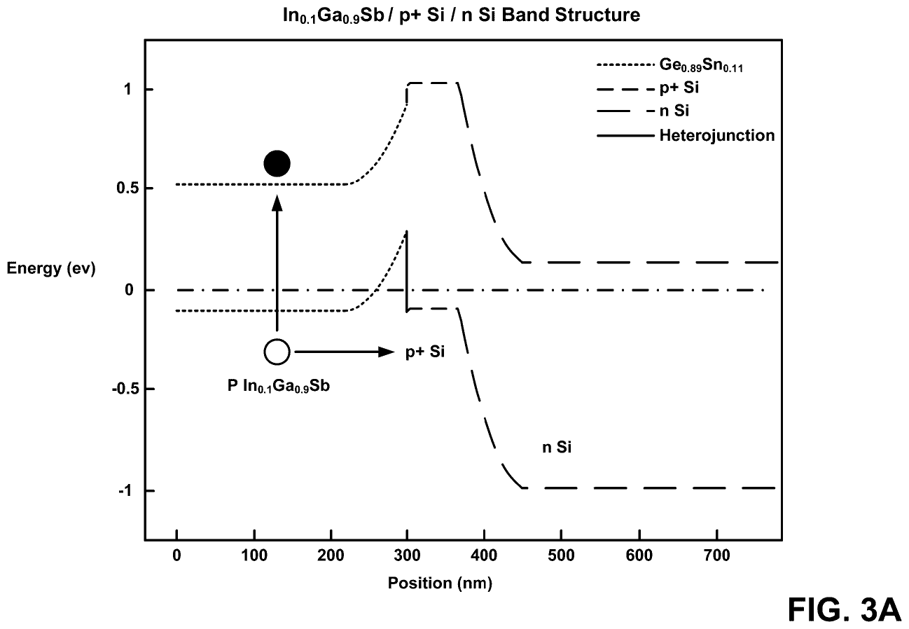

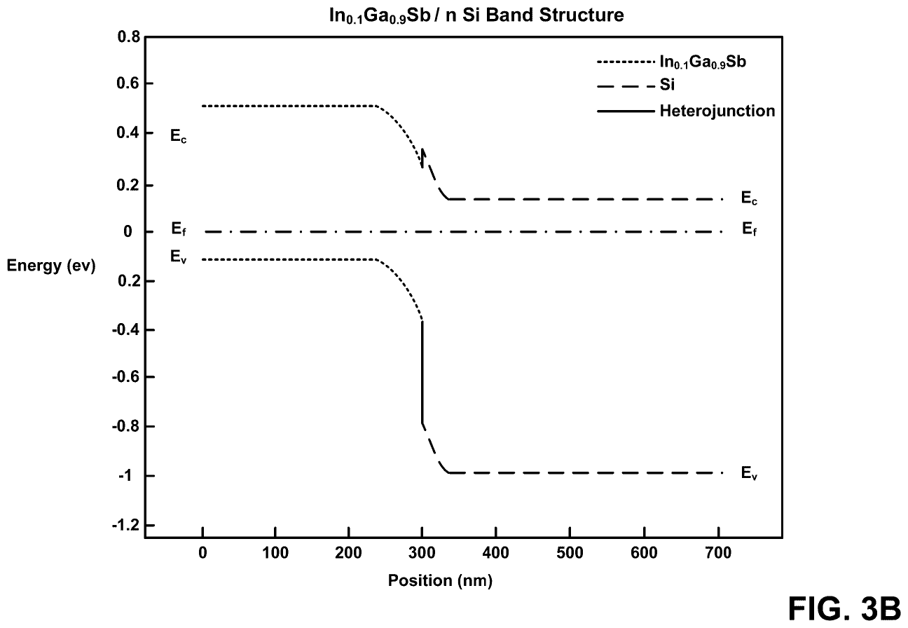

The equilibrium band diagrams for the crosscuts of FIG. 1 can be calculated with the results using Ge_{0.89}Sn_{0.11} and In_{0.1}Ga_{0.9}Sb shown in FIGS. 2A to 3B.

To this end, FIG. 2A is a graph showing the calculated band structure for Ge_{0.89}Sn_{0.11} along Cutline 1 in FIG. 1, according to one embodiment of the present disclosure. Similarly, FIG. 3A is a graph showing the calculated band structure for In_{0.1}Ga_{0.9}Sb along Cutline 1 in FIG. 1, according to one embodiment of the present disclosure. In one embodiment, as illustrated, the p⁺ Si regions in FIGS. 2A and 3A can serve as a potential barrier against photoelectron transport but collect holes generated in the IR absorber. Conversely, the p-type IR absorber/n-type heterostructure can allow electron diffusion to the n-well, as depicted in FIGS. 2B and 3B.

To this end, FIG. 2B is a graph showing the calculated band structure for Ge_{0.89}Sn_{0.11} along Cutline 2 in FIG. 1, according to one embodiment of the present disclosure. Similarly, FIG. 3B is a graph showing the calculated band structure for In_{0.1}Ga_{0.9}Sb along Cutline 2 in FIG. 1, according to one embodiment of the present disclosure. In one embodiment, he Ge_{0.89}Sn_{0.11}/n Si conduction band structure can have no barrier for electron diffusion from Ge_{0.89}Sn_{0.11} to n Si, while the In_{0.1}Ga_{0.9}Sb/Si conduction band can have a small barrier that can allow electrons to tunnel to the n Si well. Ge_{0.89}Sn_{0.11} can thus be more suited to this design as an IR absorbing layer.

### QE Estimation

In one embodiment, deposition layer thickness, minimum interdigitated structure width, target wavelength, and QE can be evaluated to obtain a greater understanding of the device.

The ideal deposition thickness of the materials can be determined using Beer-Lambert's law via

I=I₀e^{-αz} (2)

where z is the material's depth, α is the absorption coefficient, and I₀ is the initial intensity.

The ratio of the amount of light absorbed and readout to the total amount of light incident on the material, or external quantum efficiency (EQE), is

EQE=A×CP (3)

where A is the amount of incident light absorbed in the device and CP is the collection probability, or probability that the light will be readout, and is given by

CP=e^{-x/L}^{_{D}} (4)

where x is the distance from the depletion region and L_{D} is the minority carrier diffusion length. Light absorbed within the depletion region can have a 100% probability of being collected in the absence of a potential barrier. However, the CP for light outside the depletion region can exponentially decrease with distance from the depletion region. As a result,

EQE=Aout×CP+A_{depl} (5)

where Aₒᵤₜ and A_{depl} are the percentages of light absorbed outside and inside of the depletion region, respectively. A_{depl} is given by

A_{depl}=e^{-α(z-w}^{_{depl}}⁾−e^{-αz} (6)

with no potential barrier present. In the presence of a potential barrier, A_{depl} can become A_{depl}×T, the tunneling probability.

Since the CP varies as a function of length, Aₒᵤₜ can be determined for each position used. Using (2),

$${A}_{out} = {\sum }_{i = 1}^{i = 1000} ( {e}^{- α {z}_{i - 1}} - {e}^{- α {z}_{i}} ) \qquad ( 7 )$$

where i is the bin number, zᵢ=(z−w_{depl})(i)(Δzᵢ), Δzᵢ=0.001, and w_{depl} is the depletion region width. The absorption in each bin can be subtracted from the previous one so the value is not cumulative. The EQE can be determined, with the results displayed in Table 1.

The ratio of the number of carriers readout to the number of photons absorbed, or the internal quantum efficiency (IQE), can also be compared between the materials. For Ge_{0.89}Sn_{0.11}, the IQE is simply given by the collection probability CP, while the IQE for In_{0.1}Ga_{0.9}Sb is CP×T due to the potential barrier.

The refractive index can be determined, and the minimum interdigitated structure width can be determined using Snell's law, with the results shown in Table 1.

### Dark Current Estimation

In one embodiment, the dark current can be important in low-light conditions in which the photo signal can become overwhelmed by the noise. The dark current can be determined at 300 K and using a 100 mV reverse bias. The variables and equations for electrons will be stated to avoid redundancy.

The electron concentration n of the IR absorber can be determined from

n=N_{C}e^{(E}^{_{F}}^{-E}^{_{c}}^{)/kT} (8)

The change in electron concentration with respect to time, ∂n/∂t, at the IR absorber/Si interface is given by

$$\frac{\partial n}{\partial t} = \frac{1}{q} \frac{d}{dx} {J}_{n} - {R}_{bb} - {R}_{nt} \qquad ( 9 )$$

and is the dark current in the device, where Jₙ is the electron current density, R_{bb} is the band-to-band recombination term, and Rₙₜ is the transition rate from traps to the conduction band. From (8),

Jₙ=RnμₙE+qDₙ∇n (10)

where μₙ is the electron mobility, E is the electric field, and Dₙ is the diffusion constant in an n-type semiconductor. The band-to-band recombination coefficient is

R_{bb}=Bᵣ(np−nᵢ²) (11)

where Bᵣ is the recombination coefficient.

The transition rate from traps to the conduction band, Rₙₜ, from (8, 10), is

$${R}_{nt} ( x ) = {\int }_{{E}_{v}}^{{E}_{c}} {r}_{nt} ( {E}_{t} , x ) {dE}_{t} \qquad ( 12 )$$

Eₜ is the trap energy and rₙₜ is the transition rate from traps at particular energy levels to the conduction band (9, 11)

rₙₜ(Eₜ)=cₙn(1−fₜ)Dₜ−eₙfₜDₜ (13)

where cₙ is the electron capture coefficient, fₜ is the occupation function, Dₜ is the defect density of states, and eₙ is the electron thermal emission rate. ∂n/∂t is then found, with the results shown in Table 1.

### Results

As illustrated in Table 1, Ge_{0.89}Sn_{0.11}'s target wavelength extends farther into the IR regime due to its smaller bandgap. In one embodiment, the minimum interdigitated width for the structures is not a concern because of the IR absorbing layer's thickness. In_{0.1}Ga_{0.9}Sb's EQE and IQE are low because the potential barrier in its conduction band hinders electron transport to the Si. Ge_{0.89}Sn_{0.11} has more dark current because its smaller bandgap allows carriers to jump into the conduction and valence bands with less energy than in materials with larger bandgaps like In_{0.1}Ga_{0.9}Sb. To achieve 1 pA/cm² dark current with a 100 mV reverse bias, Ge_{0.89}Sn_{0.11} and In_{0.1}Ga_{0.9}Sb can be cooled to 155 K and 185 K, respectively, assuming mid-gap defect state excitation at the heterojunction interface dominates the thermal generation process over that of band-to-band processes.

TABLE 1
Simulated parameters of the detector.

| Parameter | Ge_{0.89}Sn_{0.11} | | In_{0.1}Ga_{0.9}Sb | |
|---|---|---|---|---|
| IR Absorber Bandgap | 0.48 | eV | 0.63 | eV |
| Wavelength Range | 0.4-2.1 | μm | 0.4-2.0 | μm |
| IR Absorber Thickness | 100 | nm | 100 | nm |
| External Quantum | 23% | | 0.9% | |
| Efficiency | | | | |
| Internal Quantum Efficiency | ~100% | | ~10% | |
| Minimum Interdigitated | 48 | nm | 52 | nm |
| Width | | | | |
| Eff. Trap Density Incl. | 1 × 10¹⁷/cm³ | | 1 × 10¹⁶/cm³ | |
| Heterojunction Interface | | | | |
| Dark Current at 300 K, 100 | 12.6 | mA/cm² | 0.22 | mA/cm² |
| mV Reverse Bias | | | | |
| Temp. for 1 pA/cm² Dark | 155 | K | 185 | K |
| Current | | | | |
| Potential Readout Noise (4T | <5e− | rms | <5e− | rms |
| Config.) | | | | |

As shown in Table 1, a minimum interdigitated width can be 48 nm for Ge_{0.89}Sn_{0.11}. Of course, improvements or changes in material quality or composition can change a value or range of the minimum interdigitated width. For example, the minimum interdigitated width can be greater than 1 nm, or greater than 10 nm, or greater than 30 nm, or greater than 40 nm, or 0.1 to 5 μm, or 0.5 to 2 μm.

From these calculations, a better understanding of the detector is formed. The results indicate that Ge_{0.89}Sn_{0.11} is more promising than In_{0.1}Ga_{0.9}Sb to allow photoelectron diffusion into the Si. Ge_{0.89}Sn_{0.11} extends the detector's spectral responsivity farther into the IR range with higher QE.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

Embodiments of the present disclosure may also be as set forth in the following parentheticals.

(1) An infrared detector, including a complementary metal oxide semiconductor (CMOS) image sensor; and an IR absorber layer formed on the CMOS image sensor.

(2) The detector of (1), wherein the CMOS image sensor comprises an interdigital silicon layer.

(3) The detector of either (1) or (2), wherein the IR absorber layer directly contacts the silicon layer.

(4) The detector of any one of (1) to (3), wherein the IR absorber layer includes Ge₁₋ₓSnₓ.

(5) The detector of (4), wherein the IR absorber layer includes Ge_{0.89}Sn_{0.11}.

(6) The detector of any one of (1) to (5), wherein the IR absorber layer includes In_{0.1}Ga_{0.9}Sb.

(7) The detector of any one of (1) to (6), wherein the CMOS image sensor is a silicon-based CMOS image sensor.

(8) The detector of any one of (1) to (7), wherein the IR absorber layer is a p-type IR absorber layer.

(9) The detector of any one of (1) to (8), wherein the CMOS image sensor includes an n-type silicon storage well and a partial p⁺ silicon pinning region; and the p-type IR absorber layer, when struck by photons, generates and diffuses photoelectrons and holes into the n-type silicon storage well and the partial p⁺ silicon pinning region, respectively.

(10) The detector of any one of (1) to (9), wherein the minimum interdigital width of the silicon layer is 48 nm.

(11) A method of forming an IR detector, including forming an interdigitated silicon layer on a substrate including alternating n-type silicon and p⁺ silicon fingers; and forming an IR absorber layer adjacent to and contacting the interdigitated silicon layer, the IR absorber layer being p-type.

The following provide supplementary description for the work described herein. The following are hereby incorporated by reference herein in their entirety:
A. Rogalski, “HgCdTe infrared detector material: History, status and outlook,” Reports on Progress in Physics, 2005, doi: 10.1088/0034-4885/68/10/R01.
D. Zhang et al., “High-responsivity GeSn short-wave infrared p-i-n photodetectors,” Applied Physics Letters, 2013, doi: 10.1063/1.4801957.
H. Tran et al., “Si-Based GeSn Photodetectors toward Mid-Infrared Imaging Applications,” ACS Photonics, 2019, doi: 10.1021/acsphotonics.9b00845.
R. Soref, D. Buca, and S.-Q. Yu, “Group IV Photonics: Driving Integrated Optoelectronics,” Optics and Photonics News, 2016, doi: 10.1364/opn.27.1.000032.
X. Wang et al., “GeSn on Insulators (GeSnOI) Toward Mid-infrared Integrated Photonics,” Frontiers in Physics, vol. 7, 2019, Accessed: Dec. 1, 2022. [Online]. Available: https://www.frontiersin.org/articles/10.3389/fphy.2019.00134.
S. P. Svensson, W. A. Beck, W. L. Sarney, D. Donetsky, S. Suchalkin, and G. Belenky, “Temperature dependent Hall effect in InAsSb with a 0.11 eV 77 K-bandgap,” Appl. Phys. Lett., vol. 114, no. 12, p. 122102, March 2019, doi: 10.1063/1.5081120.
E. H. Steenbergen, C. P. Morath, D. Maestas, G. D. Jenkins, and J. V. Logan, “Comparing II-VI and III-V infrared detectors for space applications,” in Infrared Technology and Applications XLV, SPIE, May 2019, pp. 299-307. doi: 10.1117/12.2519250.
R. Pierret, Semiconductor Device Fundamentals. Addison-Wesley Publishing Company, 1996.
S. M. Sze and K. K. Ng, “Physics of Semiconductor Devices, 3^{rd} Edition—Simon M. Sze, Kwok K. Ng,” Physics of Semiconductor Devices, 3rd Edition.; John Wiley & Sons, Inc.; NJ, 2007.
“Brown and Arnold—2010—Fundamentals of Laser-Material Interaction and App.pdf” Accessed: Feb. 22, 2022. [Online]. Available: https://spikelab.mycpanel.princeton.edu/papers/book02.pdf.
“Solar cells-Operating principles, technology and system applications,” in Solar Energy, 1982, p. 447. doi: 10.1016/0038-092X(82)90265-1.
B. Baert, M. Schmeits, and N. D. Nguyen, “Study of the energy distribution of the interface trap density in a GeSn MOS structure by numerical simulation of the electrical characteristics,” Applied Surface Science, vol. 291, pp. 25-30, February 2014, doi: 10.1016/j.apsusc.2013.09.022.
M. Sakhaf and M. Schmeits, “Capacitance and conductance of semiconductor heterojunctions with continuous energy distribution of interface states,” Journal of Applied Physics, vol. 80, no. 12, pp. 6839-6848, December 1996, doi: 10.1063/1.363750.
W. Dou, “High-Sn-content GeSn Alloy towards Room temperature Mid Infrared Laser,” University of Arkansas, Fayetteville.

1. An infrared (IR) detector, comprising, comprising:
a complementary metal oxide semiconductor (CMOS) image sensor; and
an IR absorber layer formed on the CMOS image sensor.

2. The IR detector of claim 1, wherein the CMOS image sensor comprises an interdigital silicon layer.

3. The IR detector of claim 2, wherein the IR absorber layer directly contacts the silicon layer.

4. The IR detector of claim 1, wherein the IR absorber layer includes Ge₁₋ₓSnₓ.

5. The IR detector of claim 4, wherein the IR absorber layer includes Ge_{0.89}Sn_{0.11}.

6. The IR detector of claim 1, wherein the IR absorber layer includes In_{0.1}Ga_{0.9}Sb.

7. The IR detector of claim 1, wherein the CMOS image sensor is a silicon-based CMOS image sensor.

8. The IR detector of claim 7, wherein the IR absorber layer is a p-type IR absorber layer.

9. The IR detector of claim 8, wherein the CMOS image sensor includes an n-type silicon storage well and a partial p⁺ silicon pinning region; and
the p-type IR absorber layer, when struck by photons, generates and diffuses photoelectrons and holes into the n-type silicon storage well and the partial p⁺ silicon pinning region, respectively.

10. A method of forming an IR detector, comprising:
forming an interdigitated silicon layer on a substrate including alternating n-type silicon and p+ silicon fingers; and
forming an IR absorber layer adjacent to and contacting the interdigitated silicon layer, the IR absorber layer being p-type.
